(19) United States
(12) Patent Application Publication
(10) Pub. No.: US 2015/0069426 A1
(43) Pub. Date: Mar. 12, 2015

(54) DISPLAY PANEL

(71) Applicant: Samsung Display Co., Ltd., Yongin-City (KR)

(72) Inventors: Hyungjune KIM, Anyang-si (KR); Osung SEO, Seoul (KR)

(73) Assignee: Samsung Display Co., Ltd., Yongin-City (KR)

(21) Appl. No.: 14/220,820

(22) Filed: Mar. 20, 2014

(30) Foreign Application Priority Data
Sep. 6, 2013 (KR) 10-2013-0107451

(51) Int. Cl. H01L 27/12

(52) U.S. Cl. CPC H01L 27/1248
USPC 257/88

(57) ABSTRACT

Provided is a display panel including a base substrate provided with a plurality of thin film transistors, the base substrate including a plurality of transmission regions and a light-blocking region adjacent to the transmission regions, the thin film transistors overlapping the light-blocking region, a plurality of pixel electrodes overlapping the transmission regions, respectively, the pixel electrodes being connected to a corresponding one of the thin film transistors, and an insulating layer interposed between the pixel electrodes and the base substrate to include at least one staircase portion, each of which overlaps the transmission regions, respectively.

### CROSS-REFERENCE TO RELATED APPLICATIONS

This U.S. non-provisional patent application claims priority under 35 U.S.C. §119 to Korean Patent Application No. 10-2013-0107451, filed on Sep. 6, 2013, in the Korean Intellectual Property Office, the entire contents of which are hereby incorporated by reference.

### BACKGROUND

Example embodiments of the inventive concept relate to a display panel, and in particular, to a display panel with an improved display quality.

Flat-type display devices have been developed to replace cathode-ray tube display devices having a high thickness and consuming a high power. For example, an organic light emitting display device, a liquid crystal display device, a plasma display device, and so forth may be categorized as the flat-type display device.

The display devices include a plurality of pixels and a plurality of signal lines providing signals to the plurality of pixels. Each of the pixels includes a thin film transistor connected to a corresponding one of the signal lines. An operation of each of the pixels can be controlled by a data voltage applied to the corresponding signal line. By operating the pixels, it is possible to display a desired image.

### SUMMARY

Example embodiments of the inventive concept provide a display panel configured to be able to prevent a color of pixel from being unintentionally changed by an insulating layer.

According to example embodiments of the inventive concepts, a display panel may include a base substrate provided with a plurality of thin film transistors. The base substrate includes a plurality of transmission regions and a light-blocking region adjacent to the transmission regions. The thin film transistors overlap the light-blocking region, and a plurality of pixel electrodes overlap the transmission regions, respectively. The pixel electrodes are connected to a corresponding one of the thin film transistors, and an insulating layer is interposed between the pixel electrodes and the base substrate to include at least one staircase portion, each of which overlaps the transmission regions, respectively.

In example embodiments, the insulating layer may include a first region having a first thickness, and a second region having a second thickness different from the first thickness, the second region being provided adjacent to the first region. A depth of the staircase portion may be the same as a difference between the first and second thicknesses.

In Example Embodiments, the Depth of the Staircase Portion Ranges from 500 Å to 1000 Å. Further, the First and Second Regions have Substantially the Same Area.

In example embodiments, in plan view, the first region may be formed at a central region of the transmission region, and the second region may be provided to enclose an edge of the first region.

In example embodiments, a thickness of the insulating layer may be greater in the first region than in the second region, and the staircase portion may be overlapped with the first region.

In example embodiments, a thickness of the insulating layer may be smaller in the first region than in the second region, and the staircase portion may overlap the second region.

In example embodiments, the first region may include a plurality of first partial regions, and the second region may be between the first partial regions.

In example embodiments, the second region may include a plurality of second partial regions, and the first and second partial regions may be provided in an alternating manner.

In example embodiments, the transmission regions may include a first transmission region and a second transmission region, and the first and second transmission regions have different areas from each other. Further, a depth of the staircase portion overlapped with the first transmission region may be different from that of the staircase portion overlapped with the second transmission region.

In example embodiments, the display panel may further include a color filter layer between the insulating layer and the pixel electrode, and the color filter layer may include a plurality of color patterns.

According to example embodiments of the inventive concepts, a display panel may include a first display substrate, to which an external light may be configured to be incident, and a second display substrate disposed to face the first display substrate. The first display substrate may include a base substrate including at least one pixel region, in which at least one transmission region and a light-blocking region adjacent to the at least one transmission region may be provided, a pixel electrode provided on the base substrate and overlapped with the at least one transmission region, and an insulating layer interposed between the pixel electrodes and the base substrate to include a staircase portion overlapped with a portion of the at least one transmission region.

In example embodiments, the display panel may further include a color filter layer provided between the insulating layer and the first electrode, and the color filter layer may include a plurality of color patterns.

In example embodiments, the plurality of color patterns may be provided to correspond to the plurality of transmission regions, respectively, and each of the staircase portions overlapped with the plurality of transmission regions may have a depth dependent on a color of the corresponding color pattern associated therewith.

In example embodiments, the display panel may further include a liquid crystal layer hermetically provided between the first and second display substrates.

In example embodiments, the second display substrate may include a light-blocking pattern provided on the second display substrate to define the light-blocking region, and a second electrode provided on the light-blocking pattern configured to produce an electric field in conjunction with the first electrode. The insulating layer may include silicon nitride.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram illustrating a display device according to example embodiments of the inventive concept.

FIG. 2 is a perspective view illustrating a portion of the display panel of FIG. 1.

FIG. 3 is a plan view illustrating a portion of a display panel according to example embodiments of the inventive concept.

FIG. 4 is a sectional view taken along a line I-I′ of FIG. 3.

FIG. 5 is a sectional view taken along a line II-II′ of FIG. 3.

FIG. 6 is reflection spectrums obtained from a display panel according to example embodiments of the inventive concept.

FIG. 7 is a sectional view illustrating a portion of a display panel according to example embodiments of the inventive concept.

FIG. 8A is a plan view illustrating a portion of an insulating layer according to example embodiments of the inventive concept.

FIGS. 8B and 8C are sectional views taken along a line III-III′ of FIG. 8A in accordance with various embodiments.

FIGS. 9A and 9B are plan views illustrating a portion of an insulating layer according to example embodiments of the inventive concept.

FIG. 10A is a plan view illustrating a portion of an insulating layer according to example embodiments of the inventive concept.

FIGS. 10B and 10C are sectional views taken along a line IV-IV′ of FIG. 10A in accordance with various embodiments.

FIG. 11 is a plan view illustrating a portion of a display panel according to example embodiments of the inventive concept.

FIG. 12 is a plan view illustrating a portion of an insulating layer according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown.

Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that teems, such as those defined in commonly-used dictionaries, should be interpreted as having a meaning that is consistent with their meaning in the context of the relevant art and will not be interpreted in an idealized or overly formal sense unless expressly so defined herein.

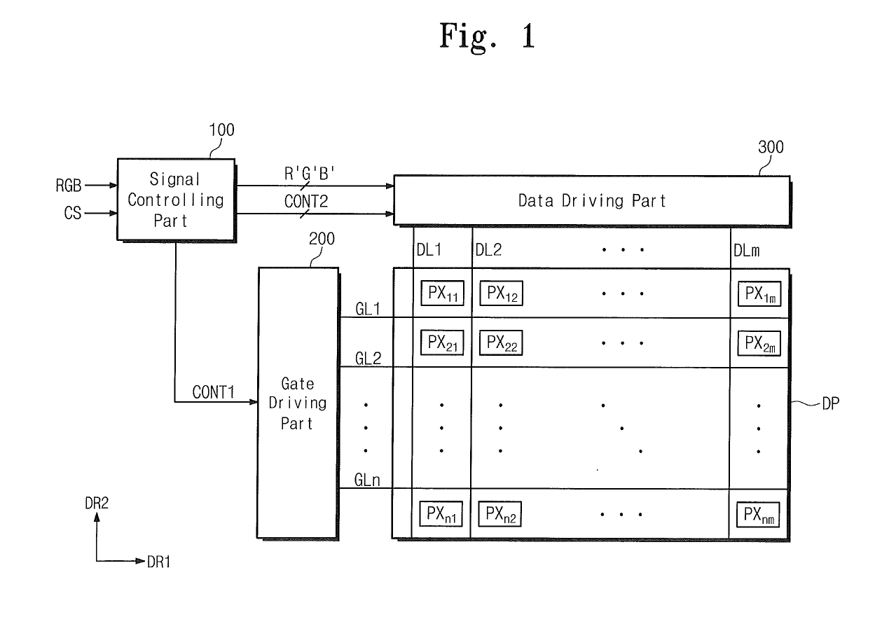

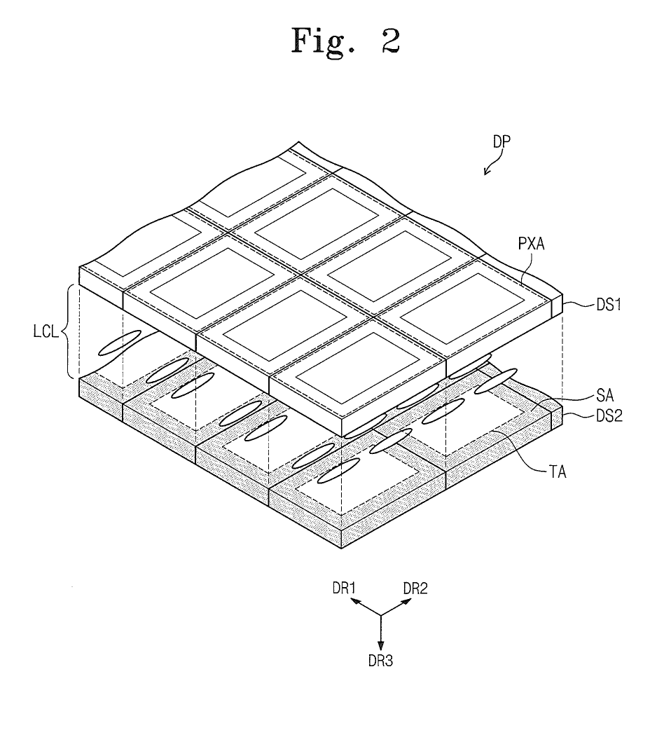

FIG. 1 is a block diagram illustrating a display device according to example embodiments of the inventive concept. FIG. 2 is a perspective view illustrating a portion of the display panel of FIG. 1.

According to example embodiments of the inventive concept, the display device may include a display panel DP, a signal controlling part 100, a gate driving part 200, and a data driving part 300. The display panel DP may not be limited to a particular type. For example, a liquid crystal display panel, an organic light emitting display panel, an electrophoresis display panel, or an electrowetting display panel may be used as the display panel DP.

In the present embodiment, a liquid crystal display device with a liquid crystal display panel will be described as an example of the display device, for the sake of brevity. The liquid crystal display panel DP may include a pair of display substrates DS1 and DS2 and a liquid crystal layer LCL interposed between the display substrates DS1 and DS2.

Although not shown, the liquid crystal display device may further include a backlight unit (not shown) providing light to the display panel DP and a pair of polarizing plates (not shown). Further, the liquid crystal display panel may be operated in one of a vertical alignment (VA) mode, a patterned vertical alignment (PVA) mode, an in-plane switching (IPS) mode, or a fringe-field switching (FFS) mode, and a plane-to-line switching (PLS) mode, but example embodiments of the inventive concepts may not be limited thereto.

The display panel DP may include a plurality of signal lines and a plurality of pixels PX₁₁-PXₙₘ connected to the signal lines. The plurality of signal lines may include a plurality of gate lines GL1-GLn and a plurality of data lines DL1-DLm. The plurality of gate lines GL1-GLn may extend along a first direction DR1, and the plurality of data lines DL1-DLm may be arranged along a second direction DR2. The plurality of data lines DL1-DLm may be provided to cross the plurality of gate lines GL1-GLn. Further, the data lines DL1-DLm may be electrically separated from the gate lines GL1-GLn.

The plurality of pixels PX₁₁-PXₙₘ may be arranged in a matrix shape. Each of the pixels PX₁₁-PXₙₘ may be connected to a corresponding one of the gate lines GL1-GLn and a corresponding one of the data lines DL1-DLm.

The plurality of gate lines GL1-GLn, the plurality of data lines DL1-DLm, and the plurality of pixels PX₁₁-PXₙₘ may be provided on an upper one (hereinafter, referred as to a first display substrate DS1) of the display substrates DS1 and DS2. However, example embodiments of the inventive concepts may not be limited thereto. For example, in other embodiments, the plurality of signal lines may be provided on a lower one (hereinafter, referred as to a second display substrate DS2) of the display substrates DS1 and DS2.

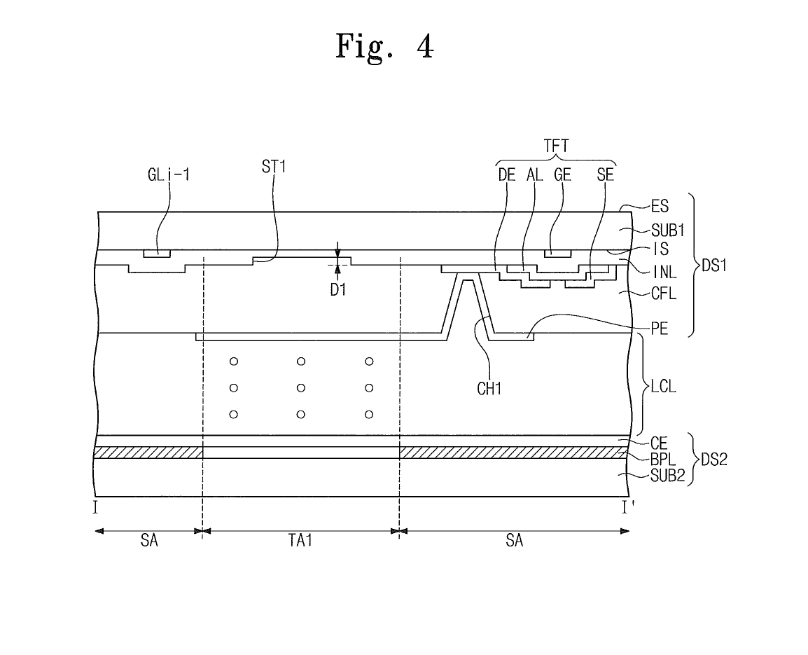

The second display substrate DS2 may be provided spaced apart from the first display substrate DS1 in a thickness direction DR3 or a third direction. In the present specification, an expression of “be disposed on a layer” may be used to represent that at least two different layers are stacked one on another in the thickness direction. A light-blocking pattern BPL (e.g., of FIG. 4) may be provided on the second display substrate DS2. The first display substrate DS 1 and the second display substrate DS2 will be described in more detail below.

The display panel DP may include a plurality of pixel regions PXA. In example embodiments, the pixels PX₁₁-PXₙₘ may be disposed on the pixel regions PXA, respectively. Alternatively, the display panel DP may include a plurality of transmission regions TA and at least one light-blocking region SA adjacent to the transmission regions TA. Each of the pixel regions PXA may be overlapped with a corresponding one of the transmission regions TA and a portion of the light-blocking region SA.

Although not shown, a backlight unit may be provided below the second display substrate DS2 (for example, in the third direction D3). The plurality of transmission regions TA may be configured to allow light generated from the backlight unit to pass therethrough. The light-blocking region SA may be configured to prevent the light generated from the backlight unit from passing therethrough. The plurality of gate lines GL1-GLn and the plurality of data lines DL1-DLm may be provided to be overlapped with the light-blocking region SA.

The signal controlling part 100 may receive input image signals RGB and convert the input image signals RGB into image data R′G′B′ that can be used in the display panel DP. Further, the signal controlling part 100 may receive a variety of control signals CS (e.g., vertical synchronization signals, horizontal synchronization signals, main clock signals, and data enable signals) and output first and second control signals CONT1 and CONT2.

The gate driving part 200 may output gate signals to the plurality of gate lines GL1-GLn in response to the first control signal CONT1 from the signal controlling part 100. The first control signal CONT1 may include a vertical start signal for triggering an operation of the gate driving part 200, a gate clock signal for determining an output time of a gate voltage, an output enable signal for determining an on-pulse width of the gate voltage, and so forth.

The data driving part 300 may receive the second control signal CONT2 and the image data R′G′B′. The data driving part 300 may convert the image data R′G′B′ into data voltages and provide the converted data voltages to the data lines DL1-DLm.

The second control signal CONT2 may include a horizontal start signal for triggering an operation of the data driving part 300, an inverting signal for inverting a polarity of the data voltage, an output order signal for determining an output time of the data voltages to be output from the data driving part 300, and so forth.

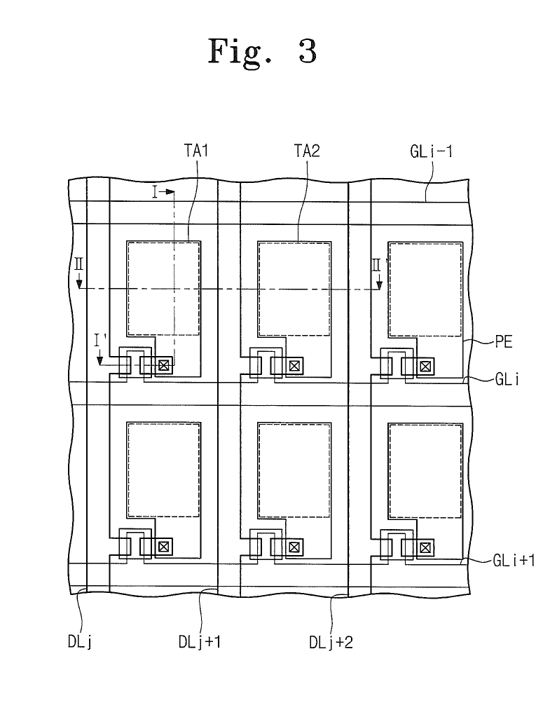

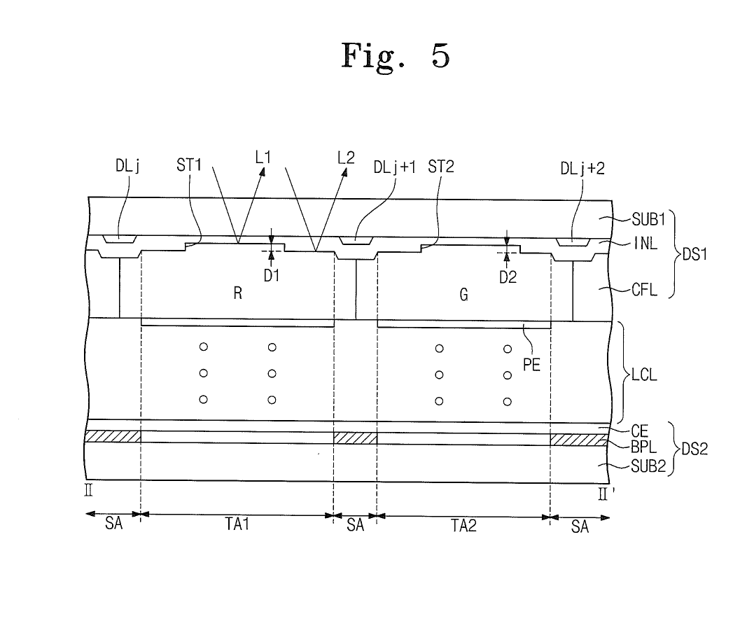

FIG. 3 is a plan view illustrating a portion of a display panel according to example embodiments of the inventive concept, FIG. 4 is a sectional view taken along a line I-I′ of FIG. 3, and FIG. 5 is a sectional view taken along a line II-IF of FIG. 3. In order to reduce complexity in the drawings and to provide better understanding of example embodiments of the inventive concept, a portion of the first display substrate DS 1 is illustrated in FIG. 3.

The first display substrate DS 1 may include a first base substrate SUB 1 having an internal surface IS and an external surface ES facing each other. The gate lines GLi−1, GLi, and GLi+1 and the data lines DLj, DLj+1, and DLj+2 may be provided on the internal surface IS, and an external light may be incident through the external surface ES. The incident light may propagate through the first base substrate SUB1 and then be reflected to the outside by elements disposed on the internal surface. The first base substrate SUB1 may be a transparent substrate (such as a glass substrate, a plastic substrate, or a silicon substrate).

The plurality of pixels PX₁₁-PXₙₘ may be provided on the base substrate SUB 1. Each of the pixels PX₁₁-PXₙₘ may be connected to a corresponding one of the gate lines GLi−1, GLi, and GLi+1 and a corresponding one of the data lines DLj, DLj+1, and DLj+2. Each of the pixels PX₁₁ may include a thin film transistor TFT and a pixel electrode PE. The thin film transistor TFT may be provided to be overlapped with the light-blocking region SA. The pixel electrode PE may be provided to be overlapped with the transmission region TA.

The thin film transistor TFTᵢⱼ may include a gate electrode GE, a source electrode SE, a drain electrode DE, and a semiconductor layer AL. The gate electrode GE may be connected to a corresponding one of the gate lines GLi−1, GLi, and GLi+1.

The gate electrode GE may be formed of the same material as that for the gate lines GLi−1, GLi, and GLi+1 and have the same layer structure as the gate lines GLi−1, GLi, and GLi+1. The gate electrode GE and the gate lines GLi−1, GLi, and GLi+1 may include a material having low reflectance. For example, the gate electrode GE and the gate lines GLi−1, GLi, and GLi+1 may include at least one of titanium, indium-zinc oxide, or copper. Further, the gate electrode GE and the gate lines GLi−1, GLi, and GLi+1 may be provided to have a multi-layered structure including at least one material.

An insulating layer INL, sometimes called a gate insulating layer INL, may be provided on the gate electrode GE. The insulating layer INL may separate the gate electrode GE electrically from other conductive elements. In example embodiments, the insulating layer INL may serve as a gate insulating layer of the thin film transistor.

The insulating layer INL may be provided to cover the gate electrode GE and the gate lines GLi−1, GLi, and GLi+1. The insulating layer INL may be formed of an inorganic material (e.g., of silicon oxide or silicon nitride). In example embodiments, the insulating layer INL may include at least one inorganic material and be configured to have a multi-layered structure.

The insulating layer INL may be provided to have at least one staircase portion. The staircase portion may be disposed to be overlapped with the transmission region TA. The formation of the staircase portion may include removing a portion of the insulating layer INL, and thus, there is a difference in thickness between the staircase portion and other portion of the insulating layer INL. In other words, the staircase portion has a depth that is equivalent to the difference in thickness between the staircase portion and other portion.

As shown in FIGS. 4 and 5, the gate insulating layer INL may be provided in the form of a single body and be provided to cover wholly a surface of the base substrate SUB1. Here, the gate insulating layer INL may be configured to include a plurality of staircase portions. Each of the staircase portions may be overlapped with a corresponding one of the transmission regions TA. For example, as exemplarily shown in FIGS. 4 and 5, the gate insulating layer INL may be provided to include first and second staircase portions ST1 and ST2 overlapped with first and second transmission regions TA1 and TA2, respectively.

The first staircase portion ST1 may have a first depth D1, and the second staircase portion ST2 may have a second depth D2. The first and second depths D1 and D2 may be the same as or different from each other. The depth of each of the staircase portions may be changed depending on the color of the corresponding transmission region. For example, in the case where the first and second transmission regions TA1 and TA2 display different colors from each other, the first and second depths D1 and D2 may be different from each other. This will be described in more detail below.

The semiconductor layer AL may be disposed on the gate insulating layer INL. The semiconductor layer AL may be overlapped with the gate electrode GE. The semiconductor layer AL may be overlapped with the light-blocking region SA. An ohmic contact layer (not shown) may be provided on the insulating layer INL.

The data lines DLj and DLj+1 may be provided on the insulating layer INL. The data lines DLj and DLj+1 may include a conductive material. The source electrode SE may be connected to one of the data lines DLj and DLj+1. The source electrode SE may be formed of the same material as that for the data lines DLj and DLj+1 and have the same layer structure as the data lines DLj and DLj+1.

On the insulating layer INL, the drain electrode DE may be disposed spaced apart from the source electrode SE. The source electrode SE and the drain electrode DE may be overlapped with a portion of the semiconductor layer AL.

The first display substrate DS1 may include an organic layer provided on the insulating layer INL. The organic layer may contribute to planarize the insulating layer INL. In example embodiments, the organic layer may serve as a color filter layer CFL. In other words, in the display device, the color filter layer CFL may be provided on the thin film transistor TFT. The color filter layer CFL may include color patterns R, G, and B, which are disposed on the plurality of pixels PX₁₁-PXₙₘ, respectively. For example, each of the color patterns may be configured to display one color of red, green, blue, or white.

As shown in FIG. 5, a boundary between the color patterns R and G may be positioned on each of the data lines DLj, DLj+1, and DLj+2. However, example embodiments of the inventive concept may not be limited to this example. For example, the color patterns R and G may be stacked one on another, on a portion of the light-blocking region SA, or the color patterns for displaying the same color may be disposed adjacent to each other.

The color filter layer CFL may be provided on the insulating layer INL to cover the staircase portions ST1 and ST2. In example embodiments, the color filter layer CFL may be provided to reduce a difference in depths D1 and D2 of the insulating layer INL and planarize a top surface of the insulating layer INL.

Although not shown, a capping layer may be further provided on the color filter layer CFL. The capping layer may be provided in the form of a single body and be provided to cover wholly a surface of the first base substrate SUB1.

The capping layer may be formed of an organic or inorganic material. For example, the capping layer may be an overcoat layer, which may be formed of an organic material and contribute to planarize the color filter layer CFL. Alternatively, the capping layer may be a passivation layer, which may be formed of an inorganic material and contribute to protect the color filter layer CFL and the thin film transistor TFT.

The pixel electrode PE may be provided on the color filter layer CFL or the capping layer (not shown). The pixel electrode PE may be overlapped with a corresponding one of the transmission regions TA. As shown in FIG. 4, the pixel electrode PE may be connected to the drain electrode DE of the thin film transistor TFT through a contact hole CH1. The contact hole CH1 may be formed to penetrate the color filter layer CFL and the insulating layer INL. Although not shown, a protection layer (not shown) for protecting the pixel electrode PE and an alignment layer (not shown) may be further provided on the pixel electrode PE.

The second display substrate DS2 may be provided on the first display substrate DS 1. The second display substrate DS2 may include a second base substrate SUB2, a light-blocking pattern BPL, and a second electrode CE. The light-blocking pattern BPL and the second electrode CE may be provided on a surface of the second base substrate SUB2 that is positioned adjacent to the first display substrate DS1. The second base substrate SUB2 may be formed of the same material as that for the first base substrate SUB1, but example embodiments of the inventive concepts may not be limited thereto.

The light-blocking pattern BPL may include a plurality of light-blocking patterns. A region provided with the light-blocking patterns will be referred to as “the light-blocking region SA”, and other regions will be referred to as “the transmission regions TA”. The light-blocking patterns may be overlapped with the data lines DLj, DLj+1, and DLj+2, and the thin film transistor TFT.

The light-blocking pattern BPL may prevent light propagating from the backlight unit (not shown) toward the second base substrate SUB2 from being incident into a region with the data lines DLj, DLj+1, and DLj+2 and the thin film transistor TFT. Further, the light-blocking pattern BPL may absorb an external light incident through the first base substrate SUB1 and thereby prevent the external light from being reflected by the second base substrate SUB2.

Although not shown, a planarization layer may be further provided on the light-blocking pattern BPL. The planarization layer may contribute to planarize the light-blocking pattern BPL. The second electrode CE may be provided on the light-blocking pattern BPL or the planarization layer (not shown). The second electrode CE may be disposed to face the pixel electrodes PE. The second electrode CE and the pixel electrodes PE may produce an electric field. In the present embodiment, the second electrode CE may serve as a common electrode CE, as will be referred to from now on.

The common electrode CE may be provided on substantially the whole region of the second base substrate SUB2. Although not shown, a protection layer (not shown) and an alignment layer (not shown) may be further provided on the common electrode CE to protect the common electrode CE.

The liquid crystal layer LCL may be disposed between the first display substrate DS 1 and the second display substrate DS2. The liquid crystal layer LCL may be interposed between the first display substrate DS1 and the second display substrate DS2 that are spaced apart from each other by spacers (not shown). In the liquid crystal layer LCL, orientation of liquid crystal may be controlled by the electric field applied between the pixel electrode PE and the common electrode CE.

The thin film transistor TFT may output the data voltage applied to one of the data lines DL1 in response to a gate signal from the gate line GLi. The pixel electrode PE may receive a pixel voltage corresponding to the data voltage, and the common electrode CE may receive a common voltage. Accordingly, a vertical electric field may be produced between the pixel electrode PE and the common electrode CE. The orientation of directors in the liquid crystal layer LCL may be changed by adjusting the vertical electric field.

Although not shown, the common electrode CE may be provided on the first display substrate DS1. Here, the pixel electrode PE and the common electrode CE may produce a lateral electric field. The lateral electric field may be used to change the orientation of the directors in the liquid crystal layer LCL. Although not shown, the pixel electrode PE or the common electrode CE may be formed to have a plurality of slits (not shown).

Although not shown, in the present embodiments, the display panel DP may be configured to have the first display substrate DS 1. For example, the first display substrate DS1 may include an organic light emitting device electrically connected to the thin film transistor. Although only one display substrate is provided in the display panel DP, it is possible to obtain the same technical effect.

As shown in FIG. 5, an external light may be incident through the external surface of the first display substrate DS1 and be reflected by elements provided on the first display substrate DS1. The reflected lights may be interacted (e.g., interfering) with each other. A major fraction of the reflected lights may be reflected from the transmission regions TA.

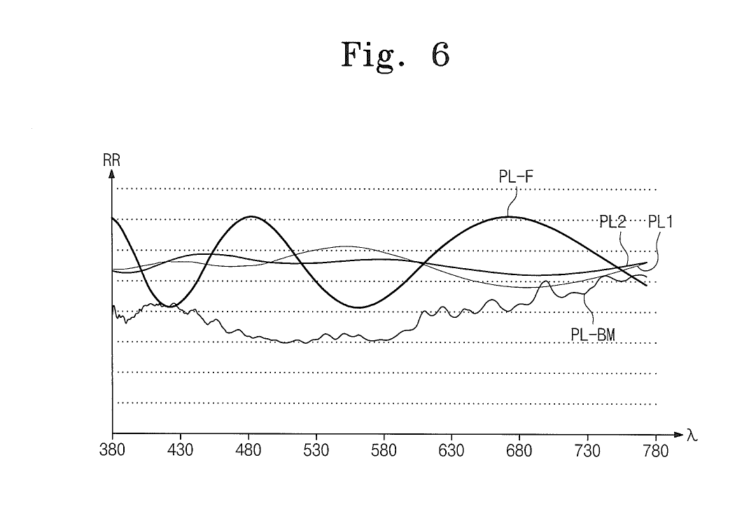

For example, a plurality of reflected lights L1 and L2 may be reflected from the insulating layer INL located on the first transmission region TA1. The insulating layer INL may have a plurality of regions having different thicknesses from each other, and thus, even when the plurality of regions are made of the same material, the lights L1 and L2 reflected from the insulating layer INL of the same transmission region TA1 can have different wavelengths from each other. This will be described in more detail with reference to FIG. 6.

FIG. 6 shows reflection spectrums PL1 and PL2 obtained from a display panel according to example embodiments of the inventive concept. To provide better understanding of example embodiments of the inventive concept, other reflection spectrums PL-BM and PL-F are also illustrated in FIG. 6. Here, the reflection spectrum PL-BM was obtained from the black matrix BM and the reflection spectrum PL-F was obtained from a display panel provided without the depth D.

The reflection spectrum PL-BM of FIG. 6, which was obtained from the black matrix BM, may correspond to a reflection spectrum from a display panel disposed at a side of the first display substrate DS1. In other words, the reflection spectrum PL-BM was obtained while minimizing optical interferences caused by other elements, such as the insulation layer of the display panel, and thus, it may serve as a reference reflection spectrum.

Each of the reflection spectrums may be given by the following equation.

$$S ( λ ) = {\sum }_{i = 1}^{n} {a}_{i} \cdot {S}_{i} ( λ ) , \qquad [ Equation 1 ]$$

where S(λ) is the reflection spectrum of the display panel comprising a plurality of insulating layers each having different thickness, aᵢ is an area ratio of a region with i-th thickness to each pixel, and Sᵢ is a reflection spectrum emitted from a region with i-th thickness. Similar to the reflection spectrum PL-F obtained from the display panel without the depth D, each of the spectrums Sᵢ may have a sinusoidal shape having peaks at specific wavelength regions. In other words, each of the spectrums Si may be expressed by a function having the wavelength as a variable.

Two or more lights having reflection spectrum different from each other may interfere with each other. Two or more lights having reflectance peaks at different wavelength ranges may affect each other. A reflection spectrum of the resultant light is a result of optical interaction between two or more lights having reflection spectrum different from each other, and thus, it can be obtained by the equation 1.

As shown in FIG. 6, the reflection spectrum PL-F obtained from the display panel provided without the depth D had a sinusoidal form, similar to that of a trigonometric function. In an effective wavelength region of 480 nm-720 nm, the reflection spectrum PL-F had a plurality of reflectance peaks. For example, the reflection spectrum PL-F may correspond to a spectrum of one of the first and second reflected light L1 and L2 of FIG. 5.

The display panel provided without the depth D absorbs or reflects lights having wavelengths corresponding to the peaks. Lights with a specific wavelength range may constructively or destructively interfere with the reflected light, thereby deteriorating a display quality of the display panel.

By contrast, the reflection spectrum PL1 had the lowered peak reflections. The reflection spectrum PL1 of FIG. 6 was obtained from the display panel provided with one staircase portion in the transmission region thereof. In detail, the reflection spectrum PL1 was a resultant spectrum of lights that were reflected from two portions having thicknesses of 3500 Å and 4100 Å. For example, the reflection spectrum PL1 was a resultant spectrum of the first and second reflected lights L1 and L2 of FIG. 5.

As shown in FIG. 6, the reflection spectrum PL1 had a lowered peak reflectance. This implies that, for an overall wavelength range, the reflectance RR of the reflection spectrum PL1 had an improved uniformity. The reflection spectrum PL1 had a lowered peak property and a broadened property in the effective wavelength range. Accordingly, it is possible to reduce a constructive or destructive interference caused by the reflection spectrum PL1. This implies that it is possible to suppress the insulating layer INL from affecting an image quality of the display panel.

The reflection spectrum PL2 is a graph obtained from the display panel with several staircase portions. In detail, the reflection spectrum PL2 was obtained from the display panel, in which four staircase portions having thicknesses of 3200 Å, 3500 Å, 4100 Å, and 4400 Å were provided. As shown in FIG. 6, a peak amplitude of the reflection spectrum PL2 was decreased compared with that of the reflection spectrum PL1.

In other words, based on the equation 1, the larger the number n of the staircase portions, the larger number of spectrums combining together. In turn, the larger number of the spectrums, the lower the peak amplitude of one light's spectrum. Further, the larger the number n of the staircase portions, the broader the reflectance of the spectrum over the effective wavelength range. As a result, a peak reflection amplitude of the resulting interference spectrum was attenuated or substantially vanished. According to example embodiments of the inventive concept, the display panel may be configured to include the insulating layer with at least one staircase portion in the transmission region, and this makes it possible to realize the reflection spectrum PL1 having uniform reflectance.

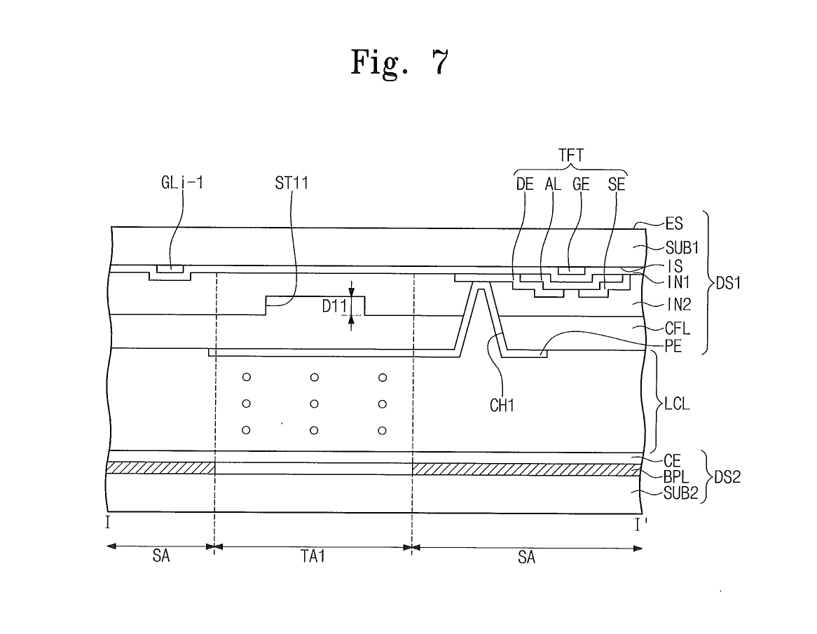

FIG. 7 is a sectional view illustrating a portion of a display panel according to example embodiments of the inventive concept. The portion of FIG. 7 may be the same region as that of FIG. 4. As shown in FIG. 7, the first display substrate DS1 may include a plurality of insulating layers IN1 and IN2. For concise description, a previously described element may be identified by a similar or identical reference number without repeating an overlapping description thereof.

The plurality of insulating layers IN1 and IN2 may include a first insulating layer IN1 and a second insulating layer IN2. The first insulating layer IN1 and the second insulating layer 1N2 may be disposed between the first base substrate SUB1 and the pixel electrode PE. In the present embodiment, the first insulating layer IN1 may serve as a gate insulating layer, as will be referred to from now on.

The second insulating layer IN2 may be disposed between the thin film transistor TFT and the pixel electrode PE. In the present embodiment, the second insulating layer IN2 may serve as a passivation layer, as will be referred to from now on. The second insulating layer IN2 may protect the thin film transistor TFT and separate the thin film transistor TFT electrically from other conductive elements.

The second insulating layer IN2 may include at least one staircase portion ST11. The staircase portion ST11 may be provided within the transmission region TA1. The staircase portion ST11 may be formed to have a shape concavely recessed by a depth D11.

The color filter layer CFL may be provided on the second insulating layer IN2. The color filter layer CFL may be formed of an organic material. The color filter layer CFL may be provided to fill the staircase portion ST11. By virtue of the presence of the color filter layer CFL, it is possible to remove the depth D11 of the staircase portion ST11 and planarize the second insulating layer IN2.

In the present embodiments, the insulating layer of the display panel may have at least one staircase portion ST11 formed within the transmission region TA1. As shown in FIG. 7, the insulating layer may have a multi-layered structure. Further, although not shown, each of the first and second insulating layers IN1 and IN2 may be formed to have the staircase portion ST11.

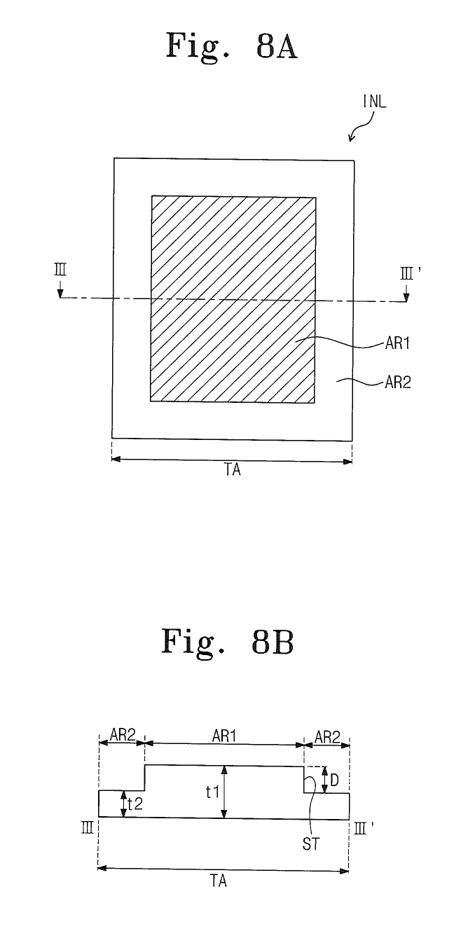

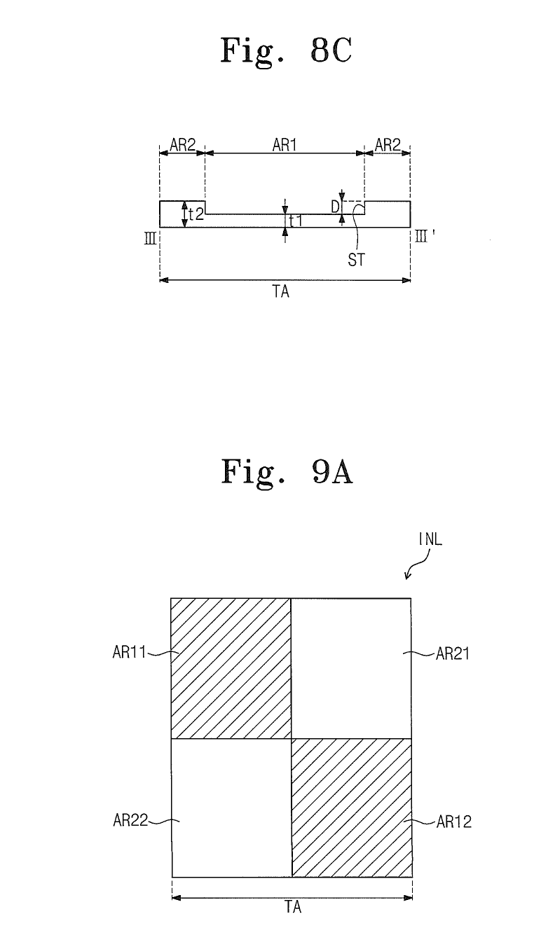

FIG. 8A is a plan view illustrating a portion of an insulating layer according to example embodiments of the inventive concept. FIGS. 8B and 8C are sectional views taken along a line of FIG. 8A in accordance with various embodiments. For example, a portion corresponding to the transmission region TA of the insulating layer INL is exemplarily illustrated in FIG. 8A.

As shown in FIG. 8A, in the transmission region TA, the insulating layer INL may include a first region AR1 and a second region AR2. The first region AR1 may have a first thickness t1 and be formed at a central region of the transmission region TA. The second region AR2 may have a second thickness t2 different from the first thickness t1 and be formed to surround the first region AR1.

The staircase portion ST may include a flat surface and a side surface extending upward from the flat surface. The side surface may serve as a boundary between the first region AR1 and the second region AR2.

In example embodiments, as shown in FIG. 8B, the first thickness t1 may be greater than the second thickness t2. In the transmission region TA, the insulating layer INL may have an outward protruding central portion and thereby have a convex shape. The staircase portion ST may be overlapped with the second region AR2. The staircase portion ST may be formed by removing partially the second region AR2 of the insulating layer INL. The depth D may be a difference between the first and second thicknesses t1 and t2.

In other example embodiments, as shown in FIG. 8C, the first thickness t1 may be smaller than the second thickness t2. In the transmission region TA, the insulating layer INL may have an inward recessed central portion and thereby have a concave shape. The staircase portion ST may be overlapped with the first region AR1. The staircase portion ST may be formed by removing partially the first region AR1 of the insulating layer INL. The depth D may be a difference between the first and second thicknesses t1 and t2.

As shown in FIGS. 8A through 8C, the first region AR1 may be formed to have the same area as that of the second region AR2, but example embodiments of the inventive concept may not be limited thereto. For example, in order to match the reflection spectrum with a reflection spectrum of the black matrix, the thickness and an area ratio may be variously adjusted on the basis of the equation 1.

In the insulating layer INL described with reference to FIGS. 8A through 8C, the depth D may be variously changed. For example, the depth D may range from 500 Å to 1000 Å. Example embodiments of the inventive concept may not be limited thereto, and in order to match the reflection spectrum with a reflection spectrum of the black matrix, the depth D and an area ratio may be variously adjusted on the basis of the equation 1.

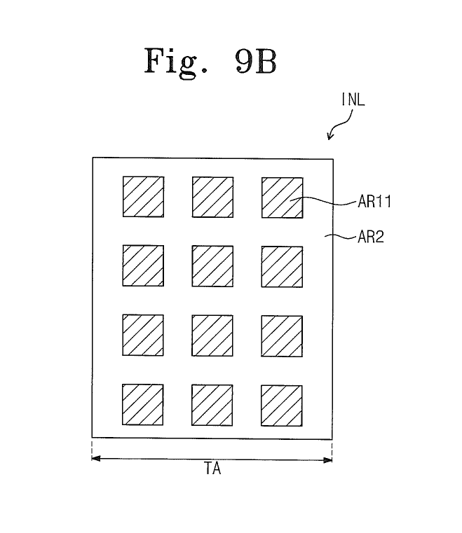

FIGS. 9A and 9B are plan views illustrating a portion of an insulating layer INL according to example embodiments of the inventive concept. FIGS. 9A and 9B show the transmission region TA. To provide better understanding of example embodiments of the inventive concept, the first region AR1 is hatched in FIGS. 9A and 9B. As shown in FIGS. 9A and 9B, a plurality of staircase portions may be provided in each transmission region TA.

As shown in FIG. 9A, the first region AR1 may include a plurality of first partial regions AR11 and AR12, and the second region AR2 may include a plurality of second partial regions AR21 and AR22. The first partial regions AR11 and AR12 and the second partial regions AR21 and AR22 may be arranged to form a matrix shape. As shown in FIG. 9A, a sum of areas of the first partial regions AR11 and AR12 may be substantially equivalent to that of the second partial regions AR21 and AR22. However, example embodiments of the inventive concept may not be limited thereto. Based on the equation 1, the depth D and an area ratio may be variously changed. Further, the first partial regions AR11 and AR12 may have different areas from each other, and the second partial regions AR21 and AR22 may also have different areas from each other.

A shape of the staircase portion of the insulating layer INL may be variously changed depending on the arrangement of the first and second regions AR1 and AR2. For example, as shown in FIG. 9B, the insulating layer INL may include a plurality of the first partial regions AR11 and the second region AR2. Each of the first partial regions AR11 may have an island shape, and thus, the first partial regions AR11 may be arranged spaced apart from each other. The second region AR2 may be disposed adjacent to the first partial regions AR11.

For example, the first partial regions AR11 may have a larger thickness than the second region AR2. Here, the staircase portion of the insulating layer may have a lattice or grid shape. Alternatively, the first partial regions AR11 may have a smaller thickness than the second region AR2. The staircase portion of the insulating layer INL may be formed to include a plurality of concave patterns or a plurality of convex patterns, depending on the difference in thickness between the first partial regions AR11 and the second region AR2.

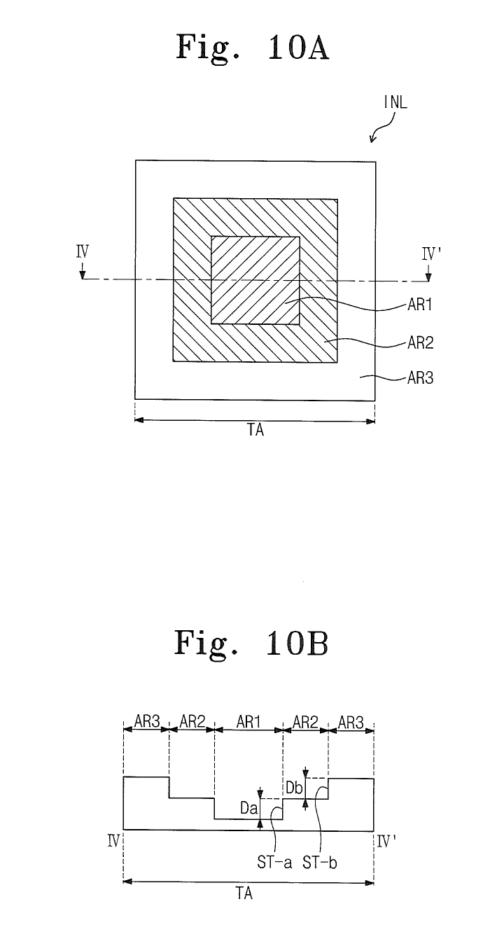

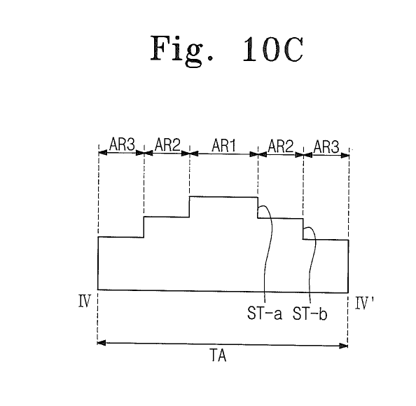

FIG. 10A is a plan view illustrating a portion of an insulating layer INL according to example embodiments of the inventive concept. FIGS. 10B and 10C are sectional views taken along a line IV-IV′ of FIG. 10A in accordance with various embodiments. According to example embodiments of the inventive concept, the insulating layer INL may include several staircase portions having a plurality of depths, in the transmission region TA.

As shown in FIGS. 10A through 10C, in plan view, the insulating layer INL may be divided into three regions. The insulating layer INL may include a first region AR1 provided at the central region of the transmission region TA and a second region AR2 provided adjacent to the first region AR1 to enclose an edge of the first region AR1. Further, the insulating layer INL may further include a third region AR3 enclosing an edge of the second region AR2.

As shown in FIGS. 10B and 10C, the insulating layer INL may include a staircase portion ST-a, which is provided between the first and second regions AR1 and AR3 to have a first depth Da, and another staircase portion ST-b, which is provided between the second and third regions AR2 and AR3 to have a second depth Db. The first depth Da and the second depth Db may be equal to or different from each other.

As shown in FIG. 10B, the staircase portion may be formed at the central region of the transmission region. The staircase portion may be overlapped with the first region AR1 and the second region AR2. The first region AR1 may be more recessed than the second region AR2, and thus, the insulating layer INL may have a concave structure.

Alternatively, as shown in FIG. 10C, the staircase portion may be overlapped with the first and second regions AR1 and AR2. The third region AR3 may be more recessed than the second region AR2, and thus, the insulating layer INL may have a convex structure.

As discussed above, in the case where a plurality of the staircase portions are formed in a portion of the insulating layer overlapped with the transmission region TA, it is possible to obtain the reflected lights having various reflection spectrums. The reflected lights may interact optically with each other and thereby exhibit the lowered peak amplitude and the uniform reflection spectrum over the effective wavelength range. Accordingly, it is possible to reduce a dependence of the reflectance of the display panel DP on the insulating layer INL and thereby control easily a color quality of the display panel DP.

Further, if light is reflected from an insulating layer having a single thickness, a reflection spectrum thereof may be shifted by a variation in thickness of the insulating layer INL. By contrast, the more the staircase portions of the insulating layer INL, the more the number of optically-interacting lights, and thus, it is possible to suppress the display quality of the display panel DP from being affected by the thickness variation of the insulating layer INL.

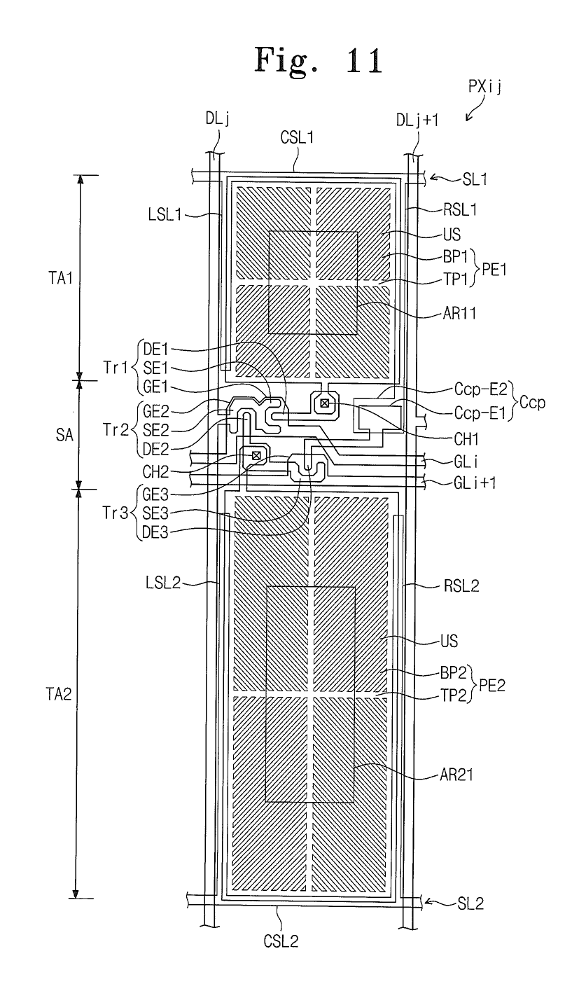

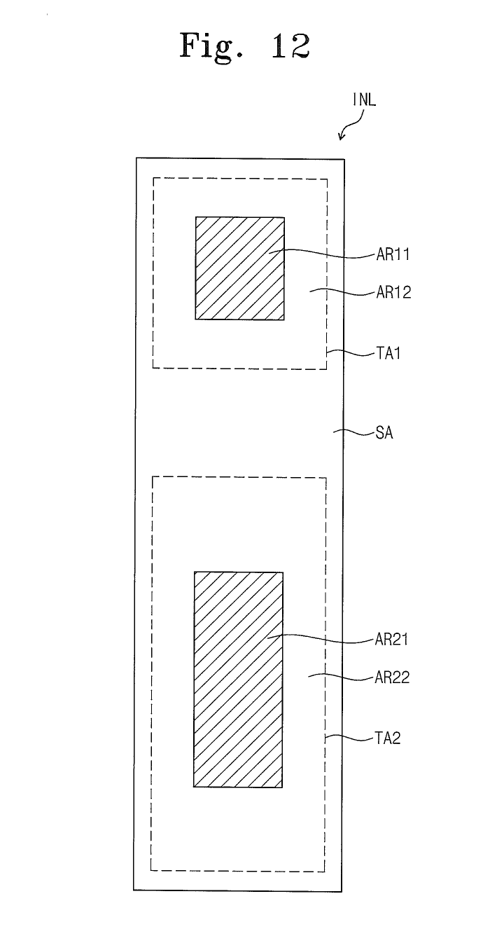

FIG. 11 is a plan view illustrating a portion of a display panel according to example embodiments of the inventive concept. FIG. 12 is a plan view illustrating a portion of an insulating layer according to example embodiments of the inventive concept. FIG. 12 shows a region of insulating layer corresponding to the pixel of FIG. 11. For concise description, a previously described element may be identified by a similar or identical reference number without repeating an overlapping description thereof.

As shown in FIGS. 11 and 12, a driving circuit DCE may be provided on the light-blocking region SA. In more detail, an i-th gate line GLi and an (i+1)-th gate line GLi+1 may be provided on the base substrate. A gate electrode GE1 of a first thin film transistor Tr1 may diverge from the i-th gate line GLi, and a gate electrode GE3 of a third thin film transistor Tr3 may diverge from the (i+1)-th gate line GLi+1.

A first storage line SL1 and a second storage line SL2 may be provided on the same layer as the i-th and (i+1)-th gate lines GLi and GLi+1. The first storage line SL1 may include a trunk electrode CSL1 and first and second branch electrodes LSL1 and RSL1 diverging from the trunk electrode CSL1. The second storage line SL2 may include a trunk electrode CSL2 and first and second branch electrodes LSL2 and RSL2 diverging from the trunk electrode CSL2.

The trunk electrode CSL1 of the first storage line SL1 may be parallel to the i-th and (i+1)-th gate lines GLi and GLi+1. The first and second branch electrode LSL1 and RSL1 of the first storage line SL1 may be disposed parallel to and spaced apart from each other.

One of electrodes constituting a coupling capacitor Ccp (hereinafter, referred to as a ‘second electrode Ccp-E2’) may be provided on the base substrate. The second electrode Ccp-E2 may be connected to the second branch electrode RSL1 of the first storage line SL 1.

A gate insulating layer (not shown) may be provided on the base substrate to cover the i-th and (i+1)-th gate lines GLi and GLi+1. The j-th and (j+1)-th data lines DLj and DLj+1 may be provided on the gate insulating layer.

The first and second thin film transistors Tr1 and Tr2 may include source electrodes SE1 and SE2 diverging from the j-th data line DLj. A source electrode SE3 of the third thin Elm transistor Tr3 may be connected to a drain electrode DE2 of the second thin film transistor Tr2. A drain electrode DE3 of the third thin film transistor Tr3 may be connected to another electrode (hereinafter, referred as to a first electrode Ccp-E1) of the coupling capacitor Ccp.

A passivation layer may be provided on the first to third thin film transistors Tr1-Tr3. The passivation layer may be formed to cover the driving circuit DCE. The passivation layer may be overlapped with a plurality of the transmission regions TA1 and TA2 and the light-blocking region SA. The transmission regions TA1 and TA2 may be formed to have different areas from each other. For example, in plan view, the first transmission region TA1 may have a smaller area than the second transmission region TA2.

A color filter layer may be provided on the passivation layer. The color filter layer may include a plurality of color patterns. The plurality of color patterns may be configured to display a color corresponding to each transmission regions.

A plurality of pixel electrodes PE1 and PE2 may be provided on the color filter layer or the passivation layer. The pixel electrodes PE1 and PE2 may include a first pixel electrode PE1 and a second pixel electrode PE2.

The first pixel electrode PE1 may be connected to a drain electrode DE1 of the first thin film transistor Tr1 through a contact hole CH1. The contact hole CH1 may be formed to penetrate the insulating layer INL and the color filter layer (not shown). A shape of the contact hole CH1 may be changed depending on a method for forming the same.

The first pixel electrode PE1 and the first storage line SL1 may be partially overlapped with each other by the insulating layer INL and the gate insulating layer interposed therebetween. The first pixel electrode PE1, the storage line SL1, and the insulating materials interposed therebetween may constitute a storage capacitor.

The first pixel electrode PE1 may include a plurality of slits dividing the first transmission region TA1 into a plurality of domains. The plurality of slits may be formed by a trunk portion TP1 and a plurality of branch portions BP 1 radially extending from the trunk portion TP1. The trunk portion TP1 may be shaped like a cross. In example embodiments, as shown, the first transmission region TA1 may be divided into four domains by the trunk portion TP1.

In each of the four domains, the branch portions BP1 may be arranged spaced apart from and parallel to each other. The branch portions BP1 of the four domains may be formed at angles of 45°, 135°, 225°, and 315° with respect to a horizontal portion of the trunk portion TP1. Adjacent ones of the branch portions BP1 may be spaced apart from each other with an order of micrometer, thereby forming fine slits US. Due to the presence of the slits US, pre-tilted directions of liquid crystal molecules in the liquid crystal layer may differ between the domains.

The second pixel electrode PE2 may be connected to the drain electrode DE3 of the third thin film transistor Tr3 through the contact hole CH2. The second pixel electrode PE2, the second storage line SL2, and the insulating materials interposed therebetween may constitute a second storage capacitor.

The second pixel electrode PE2 may include a trunk portion TP2 dividing the second transmission region TA2 into a plurality of domains and a plurality of branch portions BP2 radially extending from the trunk portion TP2. Adjacent ones of the branch portions BP2 may be spaced apart from each other with an order of micrometer, thereby forming fine slits US. Due to the presence of the fine slits US, pre-tilted directions of liquid crystal molecules in the liquid crystal layer may differ between the domains.

As shown in FIGS. 11 and 12, the insulating layer INL with a plurality of regions may be provided on each of the first and second transmission regions TA1 and TA2. The regions of the insulating layer INL may have different thicknesses from each other, and thus, the insulating layer INL may include at least one staircase portion near an interface between the regions.

The insulating layer INL may include the first region AR11 and the second region AR12 provided in the first transmission region TA1. The first region AR11 may have a first thickness and the second region AR12 may have a second thickness that is different from the first thickness. The first region AR11 may be formed at a central region of the first transmission region TA1, and the second region AR12 may be formed to enclose an edge of the first region AR11.

In example embodiments, the first region AR11 and the second region AR12 may have the same area as each other, but example embodiments of the inventive concepts may not be limited thereto. For example, an area ratio between the first and second regions AR11 and AR12 may be variously changed depending on the depth of the staircase portion.

The staircase portion may have a depth that is determined by a difference between the first and second thicknesses. The depth of the staircase portion may be changed in conjunction with the area ratio, based on the equation 1. For example, the staircase portion may have a depth of 500 Å-1000 Å, but example embodiments of the inventive concept may not be limited thereto.

The staircase portion may be overlapped with one of the first and second regions AR11 and AR12. For example, the first thickness may be larger than the second thickness. Here, the insulating layer INL may include a protruding pattern provided in the first transmission region TA1. The staircase portion may be overlapped with the second region AR12.

Alternatively, the first thickness may be smaller than the second thickness. Here, the insulating layer INL may include a concave pattern provided in the first transmission region TA1. The staircase portion may be overlapped with the first region AR11.

The insulating layer INL may include a third region AR21 and a fourth region AR22 provided in the second transmission region TA2. The third region AR21 may have a third thickness, and the fourth region AR22 may have a fourth thickness different from the third thickness. The third region AR21 may be formed at a central region of the second transmission region TA2, and the fourth region AR22 may be formed to enclose an edge of the third region AR21.

In example embodiments, the third region AR21 and the fourth region AR22 may have the same area as each other, but example embodiments of the inventive concepts may not be limited thereto. For example, an area ratio between the third and fourth regions AR21 and AR22 may be variously changed depending on the depth of the staircase portion.

The depth of the staircase portion may be determined by a difference between the third and fourth thicknesses. The depth of the staircase portion may be changed in conjunction with the area ratio, based on the equation 1. For example, the staircase portion may have a depth of 500 Å-1000 Å, but example embodiments of the inventive concept may not be limited thereto.

The staircase portion of the insulating layer INL overlapped with the second transmission region TA2 may be overlapped with one of the third and fourth regions AR21 and AR22. For example, in the case where the third thickness is greater than the fourth thickness, the staircase portion may be formed to be overlapped with the fourth region AR22.

The third thickness may be smaller than the fourth thickness. Here, the insulating layer INL may include a concave pattern provided in the second transmission region TA2. The staircase portion may be provided to be overlapped with the fourth region AR21. Upper surfaces of the second region AR12 and the fourth region AR22 may be coplanar with each other. For example, the second thickness may be substantially equal to the fourth thickness.

According to example embodiments of the inventive concept, an insulating layer in each pixel is formed to have a staircase portion, and this makes it possible to improve uniformity of reflection spectrum of the insulating layer (especially, in substantially all of the visible wavelength range). Accordingly, it is possible to prevent light of specific wavelength from being prominently displayed or to prevent color degradation from occurring, and thus, it is possible to provide the display panel with an improved display quality.

While example embodiments of the inventive concepts have been particularly shown and described, it will be understood by one of ordinary skill in the art that variations in form and detail may be made therein without departing from the spirit and scope of the attached claims.

What is claimed is:

1. A display panel, comprising:
a base substrate provided with a plurality of thin film transistors, the base substrate including a plurality of transmission regions and a light-blocking region adjacent to the transmission regions, the thin film transistors overlapping the light-blocking region;
a plurality of pixel electrodes overlapping the transmission regions, respectively, the pixel electrodes being connected to a corresponding one of the thin film transistors; and
an insulating layer interposed between the pixel electrodes and the base substrate including at least one staircase portion, each of which overlaps the transmission regions, respectively.

2. The display panel of claim 1, wherein the insulating layer comprises:
a first region having a first thickness; and
a second region having a second thickness different from the first thickness, the second region being provided adjacent to the first region,
wherein a depth of the staircase portion is the same as a difference between the first and second thicknesses.

3. The display panel of claim 2, wherein the depth of the staircase portion ranges from 500 Å to 1000 Å.

4. The display panel of claim 2, wherein the first and second regions have substantially the same area.

5. The display panel of claim 4, wherein the second region encloses an edge of the first region.

6. The display panel of claim 5, wherein a thickness of the insulating layer is greater in the first region than in the second region, and the staircase portion overlaps the first region.

7. The display panel of claim 5, wherein a thickness of the insulating layer is smaller in the first region than in the second region, and the staircase portion overlaps the second region.

8. The display panel of claim 4, wherein the first region comprises a plurality of first partial regions, and the second region is between the first partial regions.

9. The display panel of claim 8, wherein the second region comprises a plurality of second partial regions, and the first and second partial regions are provided in an alternating manner.

10. The display panel of claim 1, wherein the transmission regions comprises a first transmission region and a second transmission region, the first and second transmission regions have different areas from each other.

11. The display panel of claim 10, wherein a depth of the staircase portion overlapped with the first transmission region is different from that of the staircase portion overlapped with the second transmission region.

12. The display panel of claim 1, further comprising a color filter layer between the insulating layer and the pixel electrode, the color filter layer comprising a plurality of color patterns.

13. The display panel of claim 12, further comprising a common electrode on the color filter layer, the common and pixel electrodes configured to produce an electric field.

14. A display panel, comprising:
a first display substrate, to which an external light is configured to be incident; and
a second display substrate disposed to face the first display substrate,
wherein the first display substrate comprises:
a base substrate including at least one pixel region, in which at least one transmission region and a light-blocking region adjacent to the at least one transmission region are provided;
a pixel electrode provided on the base substrate and overlapping the at least one transmission region; and
an insulating layer interposed between the pixel electrodes and the base substrate to include a staircase portion overlapping a portion of the at least one transmission region.

15. The display panel of claim 14, wherein the at least one transmission region comprises a first transmission region and a second transmission region apart from each other,
the pixel electrode comprises a first sub-pixel electrode and a second sub-pixel electrode, which overlap the first and second transmission regions, respectively, and
the insulating layer comprises staircase portions, which are overlapped with the first and second transmission regions, respectively.

16. The display panel of claim 15, wherein the first transmission region comprises a first region and a second region, whose thicknesses are different from each other,
a depth of the staircase portion overlapped with the first transmission region is equal to a thickness difference between the first and second regions, and
the first and second regions have substantially the same area.

17. The display panel of claim 16, wherein an area of the first transmission region is different from that of the second transmission region.

18. The display panel of claim 17, wherein the staircase portion has a depth ranging from 500 Å to 1000 Å.

19. The display panel of claim 18, further comprising a liquid crystal layer hermetically provided between the first and second display substrates.

20. The display panel of claim 19, wherein the second display substrate comprises:
a light-blocking pattern provided on the second display substrate to define the light-blocking region; and
a second electrode provided on the light-blocking pattern configured to produce an electric field in conjunction with the first electrode.
